(19) United States
(12) Patent Application Publication
(10) Pub. No.: US 2013/0009663 A1
(43) Pub. Date: Jan. 10, 2013

(54) CRACK DETECTION LINE DEVICE AND METHOD

(75) Inventors: Bernd Gauch, Villach (AT); Erwin Fugger, Wernberg (AT); Alexander Mayer, Treffen (AT)

(73) Assignee: Infineon Technologies AG, Neubiberg (DE)

(21) Appl. No.: 13/178,238

(22) Filed: Jul. 7, 2011

(51) Int. Cl. G01R 31/26

(52) U.S. Cl. 324/762.01

(57) ABSTRACT

A crack detection line device and a method are disclosed. An embodiment comprises a semiconductor device comprising a crack detection line within a chip, the crack detection line surrounding an inner area of the chip, wherein the crack detection line comprises a first terminal and a second terminal. The semiconductor device further comprises a test circuit connected to the first terminal and the second terminal, the test circuit configured to measure a signal over the crack detection line and an output terminal, the output terminal connected to the test circuit and configured to provide a measured signal.

### TECHNICAL FIELD

The present invention relates generally to fabrication of semiconductor devices and, more particularly, to test structures and methods for semiconductor devices.

### BACKGROUND

Chips are generally singulated from a wafer by a cutting process. The cutting process may create or cause die-cracks or chipping in the singulated chips.

### SUMMARY OF THE INVENTION

In accordance with an embodiment of the present invention, a semiconductor device is disclosed. The semiconductor device comprises a crack detection line within a chip, the crack detection line surrounding an inner area of the chip, wherein the crack detection line comprises a first terminal and a second terminal. The semiconductor device further comprises a test circuit connected to the first terminal and the second terminal, the test circuit configured to measure a signal over the crack detection line and an output terminal, the output terminal connected to the test circuit and configured to provide a measured signal.

In accordance with an embodiment of the present invention, a method of manufacturing a semiconductor device is disclosed. The method comprises forming a crack detection line surrounding an integrated circuit, forming test circuit in the integrated circuit, the test circuit connected to the crack detection line and forming an output terminal, the output terminal connected to the test circuit.

In accordance with an embodiment of the present invention, a method for testing a semiconductor device is disclosed. The method comprises providing a semiconductor chip having a crack detection line, measuring an analog signal over the crack detection line, and reading the analog signal from an output terminal.

In accordance with an embodiment of the present invention, a semiconductor device is disclosed, the semiconductor device comprises a crack detection line within a chip, wherein the crack detection line is arranged next to a crack stop barrier surrounding an inner area of the chip, and wherein the crack detection line comprises at least one conductive segment in an interconnect structure and at least one substrate conductive segments in a substrate.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a top view of a semiconductor wafer having a plurality of chips;

FIG. 2 shows a detailed view of a single chip in the semiconductor wafer;

FIG. 3a shows a cross-sectional view of an embodiment of a crack detection line;

FIG. 3b shows a cross-sectional view of an embodiment of a crack detection line;

FIG. 3c shows a cross-sectional view of an embodiment of a crack detection line;

FIG. 3d shows a cross-sectional view of an embodiment of a crack detection line;

FIG. 4 shows a flow chart of a method to manufacture a crack detection line;

FIG. 5a shows an embodiment of test circuit;

FIG. 5b shows an embodiment of test circuit; and

FIG. 6 shows a flow chart for setting a reference value in a crack reliability test program.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

Semiconductor wafers are typically singulated into individual chips after the wafers are processed. A singulated chip comprise a semiconductor substrate and an interconnect structure thereon. The interconnect structure is a mesh of conductive lines and plugs/vias embedded in an isolation material. The isolation material is typically made from low dielectric constant material or ultra low dielectric constant material (low-k materials). Low-k materials have a k value less than the k value of silicon dioxide. Low-k materials tend to have low mechanical strength and weak adhesion properties. The chip dicing process may create cracks or delaminations within the low-k materials. The cracks may penetrate the chip and cause chip failures. Moreover, the cracks may not only damage the interconnect structure but may also propagate into the underlying semiconductor substrate.

Cracks or chippings can often be seen without the help of evaluation tools because they are visible on the surface of the chip. However, some cracks, such as hairline cracks for example, may damage the chip without being visible. Moreover, some cracks may propagate into the chip without causing damage at the time of the cutting of the chips. Rather, these cracks penetrate the interior of the chip over time so that the chip may fail after several months or years of operation. These latent chip cracks are particular damaging if the chip is used in a life saving application such as an airbag, for example.

The present invention will be described with respect to embodiments in a specific context, namely, crack detection lines for semiconductor chips. Embodiments of the invention may also be applied, however, to other applications that would benefit from crack detection lines.

Embodiments of the present invention provide a crack detection line comprising a substrate conductive segment and a metal conductive segment. Embodiments of the present invention provide test circuit configured to analog test the crack detection line. The test circuit is configured to electrically test whether or not a chip is partially damaged by cracks or chippings.

An advantage of an embodiment of the present invention is to detect cracks or chippings in the semiconductor substrate of the chip. A further advantage is to detect latent damage to the chip.

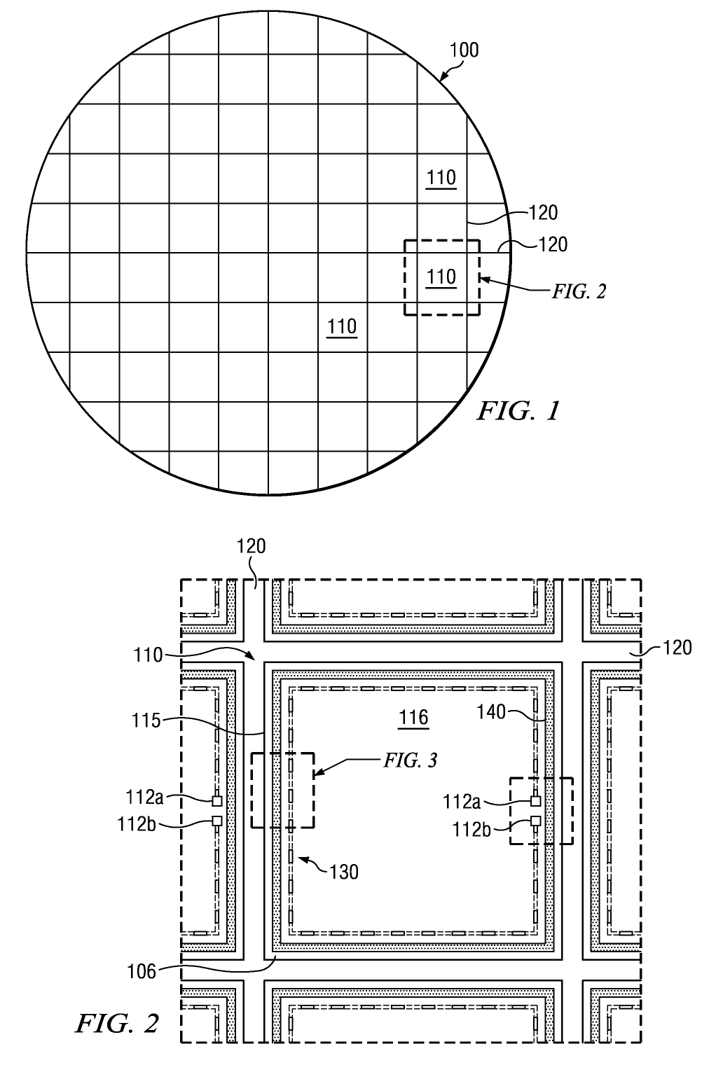

With reference now to FIG. 1, there is shown a top view of a semiconductor wafer 100 comprising a plurality of chips or dies 110 in accordance with an embodiment of the present invention. The chips 110 may be of square or rectangular shape. Each chip 110 comprises an integrated circuit or a stand alone device.

After processing the semiconductor wafer 100, the chips 110 are separated from each other at scribe lines 120 disposed between the chips 110. The scribe lines 120 are located at the perimeter of the chips 110. The chips 110 are singulated by a sawing or a laser cutting process along the scribe lines 120.

FIG. 2 is a more detailed view of a portion of the wafer 100 shown in FIG. 1, illustrating a top view of a chip 110 of FIG. 1 that includes a crack detection line 130 in accordance with an embodiment of the present invention. The crack detection line 130 is formed in at least one conductive material layer and the substrate. The crack detection line 130 may be formed proximate an optional crack stop barrier or crack prevention structure 140. In one embodiment the crack detection line 130 is formed between the edge 115 of the chip 110 and the interior region 116 of the chip 110, e.g, the integrated circuit. In another embodiment the crack detection line 110 is formed between the crack stop barrier 140 and the interior region 116 of the integrated circuit 110.

The crack prevention structure 140 comprises a metal structure formed in one or more metallization layers of the chip 110. The crack prevention structure 140 is of high mechanical strength. The crack detection lines comprises a stacked via chain in some embodiments disposed around the entire chip 110 next to the crack prevention structure 140.

The crack detection line 130 comprises a conductive structure and is disposed proximate the perimeter of the interior region 116 of the chip 110. The crack detection line 130 comprises a conductive structure disposed proximate the perimeter of the integrated circuit 116. The conductive structure may comprise a ring-like shape about the perimeter. The conductive structure may surround the inner area of the chip except for a small discontinuity in the line between a first terminal 112a and a second terminal 112b. However, the conductive structure may comprise any shape as long as the shape is able to detect cracks or chipping penetrating the inner part 116 of the chip 110. The crack detection line 130 comprises a plurality of conductive segments formed in one or more material layers and the substrate.

The crack detection line 130 may be formed in the same material layers that the crack prevention structure 140 is formed in, for example.

The crack detection line 130 may be used to detect cracks that may form when the chips 110 are separated from the wafer 100. To test the chip 110 for cracks a voltage is applied to the first terminal 112a and the second terminal 112b of the detection line 130. A current flows during the application of the voltage to the two terminals 112a/112b. If there is no (or almost no) voltage drop over the crack detection line 130, the detection line 130 is intact and a crack is not disrupted or broken. If there is some voltage drop over the crack detection line 130, the detection line may partially be broken, and if there is a complete or almost complete voltage drop over the crack detection line 130 the crack detection line may be cut or severely damaged.

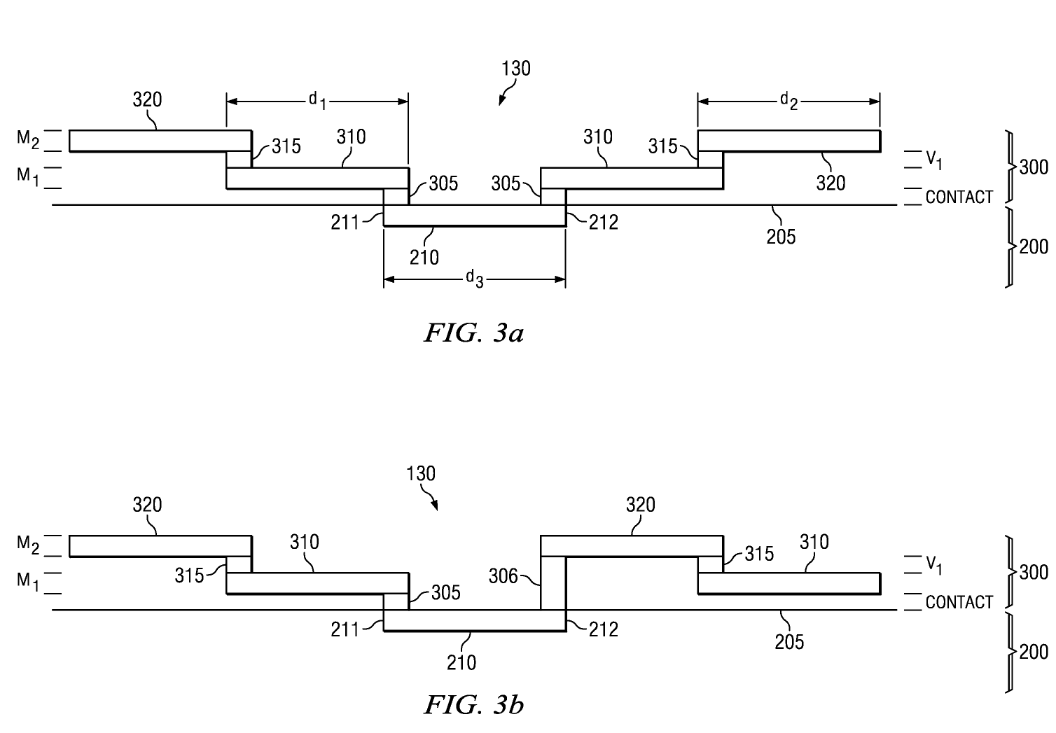

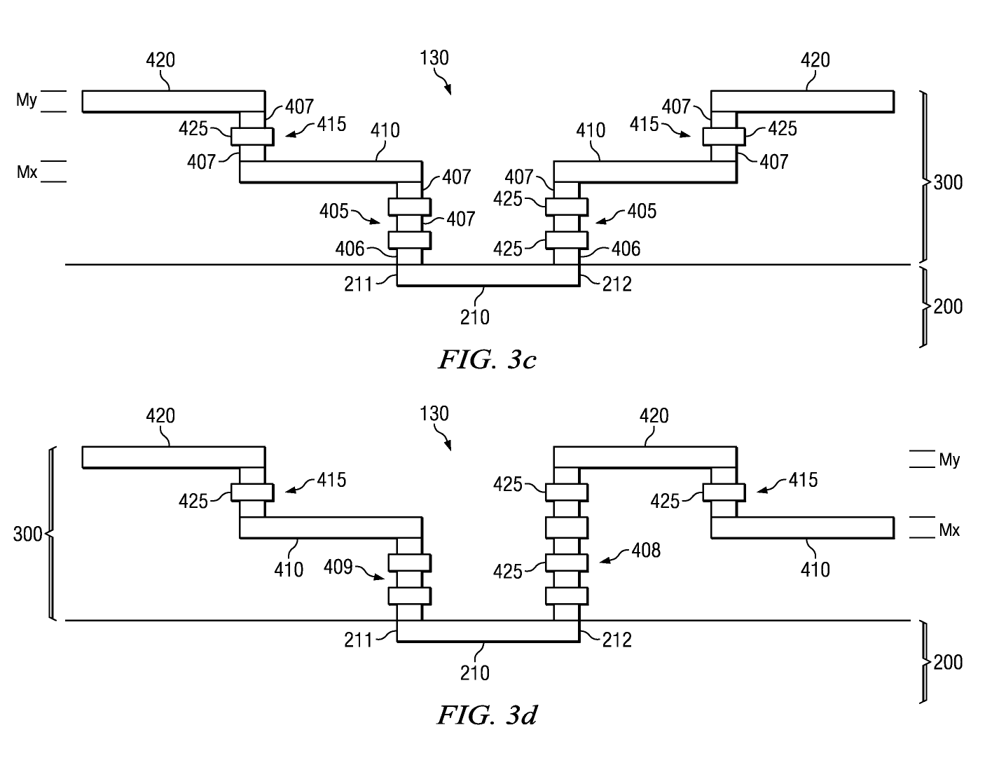

FIG. 3a shows a cross-sectional view of an embodiment of the crack detection line 130. The crack detection line 130 is formed in a semiconductor substrate 200 and the interconnect structure 300. The semiconductor substrate 200 may comprise bulk silicon or silicon-on-insulator (SOI). Alternatively, the semiconductor substrate 200 may comprise compound semiconductors such as GaAs, InP, Si/Ge, or SiC. Semiconductor components such as transistors, diodes, memory devices, MEMS, etc. may be formed in the substrate 200.

A substrate conductive segment 210 is formed in the substrate 200. The substrate conductive segment 210 may be disposed along a top surface 205 of the substrate 200 or may be embedded in the substrate 200, i.e. disposed in a distance from the top surface 205. The substrate conductive segment 210 may be formed while other implants are implanted in the substrate 200. For example, the substrate conductive segments 210 may be formed while source and drains of transistors are formed. Alternatively, the substrate conductive segments 210 may be formed in a separate implantation process step.

The substrate conductive segment 210 may comprise a doped silicon layer or an embedded metal layer. The embedded metal layer may comprise tungsten, aluminum or copper, for example. Alternatively the substrate conductive segment 210 may comprise other conductive materials such a silicides, for example.

The substrate conductive segment 210 is connected to a first M₁ conductive segment 310 at a first end 211 and to a second M₁ conductive segment 310 at a second end 212. The substrate conductive segment 210 is connected to the M₁ conductive segments 310 via contacts 305.

The M₁ conductive segment 310 is embedded in high-k or ultra high-k material. The M₁ conductive segment 310 may comprise copper, aluminum or another metal. The M₁ conductive segment 310 is disposed in the M₁ interconnect level. The M₁ conductive segment 310 is electrically connected to the substrate conductive segment 210 via the contact 305. The contact 305 is arranged in a contact layer level. The contact 305 may comprise tungsten or copper, for example.

The M₂ conductive segment 320 is embedded in the low-k materials. The M₂ conductive segment 320 may comprise copper, aluminum or another metal. The M₂ conductive segment 320 is disposed in the M₂ interconnect level. The M₂ conductive segment 320 is electrically connected to the M₁ conductive segment 310 through vias/plugs 315. The vias/plugs 315 are arranged in the V₁ via layer level. The vias/plugs 315 may comprise tungsten, aluminum or copper, or, alternatively another type of metal. The vias/plugs 315 may comprise the same material as the M₂ conductive segment 320 and/or the M₁ conductive segment 310.

The M₁ conductive segment 310 may comprise a length comprising a dimension d₁. The M₂ conductive segment 320 may comprise a length comprising a dimension d₂. The conductive substrate segment 210 may comprise a length comprising a dimension d₃. The dimensions d₁, d₂ and d₃ may be the same, or, alternatively may be different. For example, the dimension d₁, d₂ and d₃ may comprise about 2,000 nm or less in some embodiments, or may comprise greater than about 2,000 nm in other embodiments, for example. Alternatively, dimensions d₁, d₂ or d₃ may comprise other values.

FIG. 3b shows a cross-sectional view of an embodiment of the crack detection line 130. The reference numbers for the M₁ conductive segments 310, the M₂ conductive segments 320, and conductive substrate segment 210 are the same as in FIG. 3a. Moreover, the reference numbers for the contacts 305 and the plugs/vias 315 are also the same as in FIG. 3a. However, unlike in the embodiment of FIG. 3a, the substrate conductive segment 210 is directly electrically connected to the M₂ conductive segment 320 via the contact/plug 306.

FIG. 3c shows a cross-sectional view of an embodiment of the crack detection line 130. The crack detection line 130 may be used for chips with an interconnect structure of more than two metal layers. Similar to FIG. 3a, a substrate conductive segment 210 is arranged in the substrate 200. A first end 211 of the substrate conductive segment 210 is connected to a first Mₓ conductive segment 410 in the x metallization level, wherein x=1−n and n is the number of metal layers disposed in the chip. The second end 212 of the substrate conductive segment 210 is connected to a second Mₓ conductive segment 410 in the x metallization level. The first Mₓ conductive segment 410 is connected to a first M_{y} conductive segment 420 in the y metallization level, wherein y=1−n and wherein y is not equal to x. The second Mₓ conductive segment 410 is connected to a second M_{y} conductive segment 420. It is noted that x can be a higher or lower metallization level than y.

The interlayer connects 405 may comprise contacts 406 and/or plugs/vias 407. The contacts 406 and the plugs/vias 407 may be connected through small connects 425 disposed in one or more metal layer levels. The interlayer connects 415 may also be contacts 406 and/or plugs/vias 407. The contacts 406 and the plugs/vias 407 may be connected through small connects 425 disposed in one or more metal layer levels.

FIG. 3d shows a cross-sectional view of an embodiment of the crack detection line 130. Similar to FIG. 3b, the first end 211 of the substrate conductive segment 210 is connected to a first Mₓ conductive segment 410 and the second end 212 of the substrate conductive segment 210 is connected to the a first M_{y} conductive segment 420. A first interlayer connect 409 connects the substrate conductive segment 210 with the first Mₓ conductive segment 410. A second interlayer connect 408 connects the substrate conductive segment 210 with the first M_{y} conductive segment 420. The interlayer connects 415 connect the Mₓ conductive segments 410 with M_{y} conductive segments 420. Again, the interlayer connects 408, 409 and 415 may comprise contacts 406 and/or plugs/vias 407 and small connects 425.

In one embodiment the M_{y} conductive segment is connected to a M_{z} conductive segment in the z metallization level, wherein z=1−n, and wherein z is neither equal to y nor x. The M_{z} conductive segment may be connected to a substrate conductive segment, a Mₓ conductive segment or M_{y} conductive segment. Again, it is noted that z can be a higher or lower metallization level than x and/or y.

The Mₓ, M_{y}, M_{z} conductive segments may be connected through contacts 406 and/or plugs/vias 407 and connects 425.

It is noted that embodiments of FIGS. 3a -3d may be used for chips with more than two metal layers.

The conductive segments of the metal layers may be arranged in adjacent metal layers or in metal layers which are further apart from each other. For example, the crack detection line 130 may comprise only conductive substrate segments, conductive segments in the fourth metal layer, M₄, and conductive segments in the eighth metal layer, M₈. In one embodiment the crack detection line 130 may have conductive segments in the substrate and in every single level of the metal layers M₁₋ₙ up to the highest metal layer level.

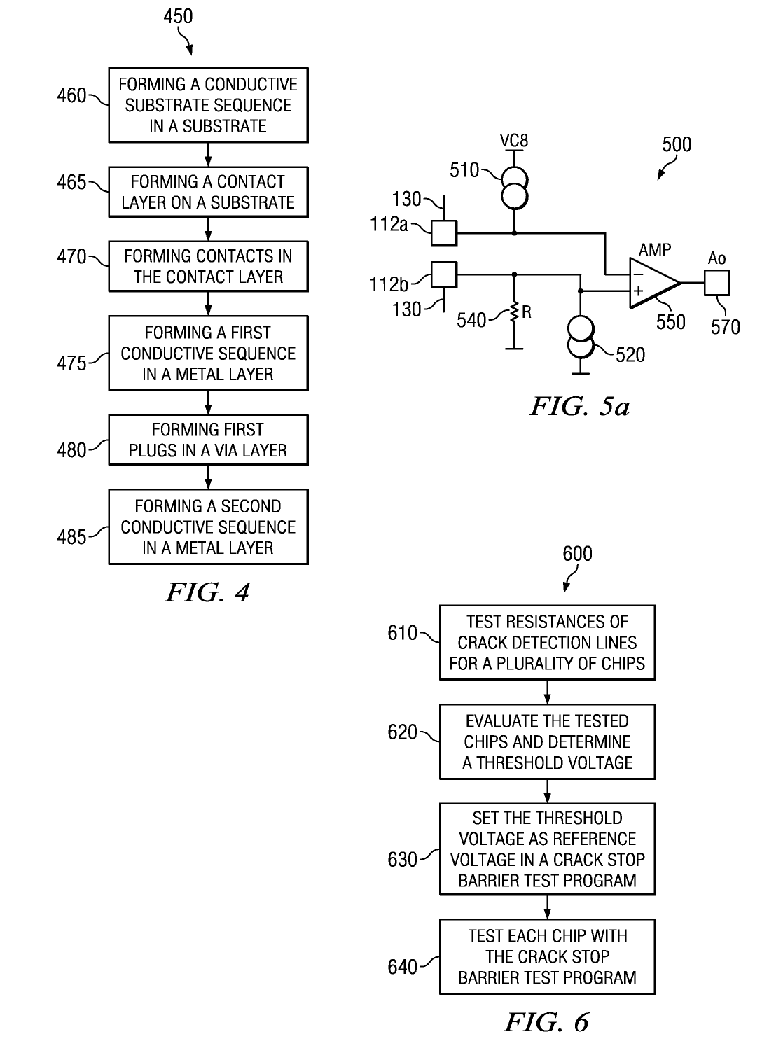

FIG. 4 shows a method 450 of manufacturing a crack detection line. In a first step 460 a conductive substrate segment is formed in a substrate. The conductive substrate segment may be formed at a top surface of the substrate or may be embedded in the substrate. In a second step 465 a contact layer may be deposited on the substrate. The contact layer may be an isolation layer. For example, the contact layer may be silicon oxide or a low-k material. In a third step 470, contacts are formed in the contact layer. The contacts may be formed so that a first contact connects to a first end of the conductive substrate segment and that a second contact connects to a second end of the conductive substrate segment.

In a fourth step 475, a first conductive segment may be disposed in a first metal layer. A first end of the first conductive segment may be connected to one of the contacts in the contact layer. The first conductive segment is formed by depositing an isolating layer over the contact layer, patterning and etching the isolating layer and filling the openings of the isolating layer with a metal such as copper or aluminum, for example. In a fifth step 480 vias are formed in a first via layer over the second end of the first conductive segment. The vias are filled with a metal such as copper or aluminum, for example, to form plugs. In a further step 485 a second conductive segment in a second metal layer. A first end of the second conductive segment is connected to the plug. The second end of the second conductive segment may be connected to a further plug in the first via layer. Alternatively, the second end of the second conductive segment may be connected to a plug in a second via layer above the second metal layer. The process can be designed for manufacturing conductive segments and plugs in all metal layer levels and via layer levels. The process 400 may be adjusted so that conductive segments are only formed in some or in selected metal layer levels.

Several single damascene processes may be repeated to form via layers Vₓ and the metallization layers Mₓ, for example. Alternatively, via Vₓ and metallization layers Mₓ, may be formed using a dual damascene process. In a dual damascene technique, a via layer and a metallization layer are formed at once, by patterning one insulating material layer using two lithography masks and processes, and then filling the patterned insulating material layer with a conductive material. The dual damascene processes may be via-first, wherein a via level such as Vₓ is patterned before a conductive line layer such as Mₓ is patterned, or via-last, wherein a conductive line layer such as Mₓ is patterned before a via level such as Vₓ is patterned, as examples.

Alternatively, the vias/plugs and the conductive segments may be patterned using a subtractive etch process, by sequentially depositing conductive material layers over the substrate and patterning the conductive material layers to form the first segments, second segments, and the third segments, and then forming an insulating material between the patterned conductive materials.

Referring again to FIG. 2, there is disclosed a first terminal 112a disposed at a first end of the crack detection line 130 and a second terminal 112b disposed at the second end of the crack detection line 130. The first terminal 112a and the second terminal 112b may comprise contacts or bond pads, for example. Alternatively, the first terminal 112a and second terminal 112b may comprise other types of electrical connections. The first terminal 112a and the second terminal 112b may comprise wire bond pads or flip chip pads in some embodiments, for example.

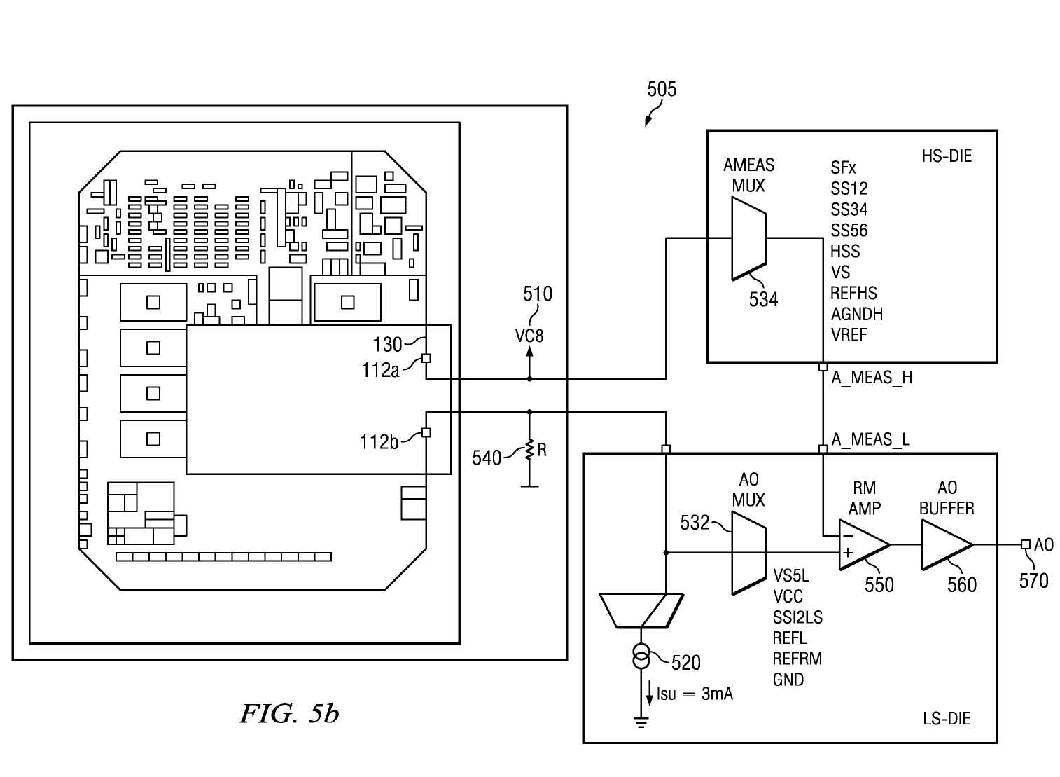

FIG. 5a shows an embodiment of a test circuit. The test circuit 500 may be implemented on the chip 110, for example, in the inner part 116 of the chip 110. The first terminal 112a of the crack detection line is electrically connected to a first input of the amplifier AMP 550 and the second terminal 112b is electrically connected to a second input of the amplifier AMP 550. A voltage source 510 may provide a voltage and a current to the test circuit 500. The amplifier AMP 550 may amplify a voltage drop over the crack detection line 130. The amplifier AMP 550 amplifies the voltage drop and the amplified voltage drop can be measured at the output AO 570.

A low voltage at the output AO 570 may indicate that the crack detection line 130 is not damaged, a high voltage at the output AO 570 may indicate that the crack detection line 130 is damaged, and a intermediate voltage level at the output AO 570 may indicate that the crack detection line 130 is partially damaged.

The test circuit 500 provides information whether the singulated chip is damaged by the singulation process. If the crack detection line is not damaged or cut there is no (or almost no) resistance along the crack detection line 130 and the voltage drops over the resistor R 540. The voltage difference at the amplifier AMP 550 and the output AO 570 is minimal. If the crack detection line 130 is cut the resistance in the crack detection line 130 is high and the complete voltage drops over the crack detection line 130. No voltage drop is measured at the resistor R 540. The difference in voltage at the AMP 550 and the output AO 570 is high. If the crack detection line is damaged but not cut there is some resistance along the crack detection line 130. A voltage may drop over the crack detection line 130 and a voltage may drop over the resistor R 540. The detected voltage difference at the amplifier AMP 550 may indicated how badly the crack detection line is damaged.

Optional transistor R 540 may provide a resetting reference voltage. The resetting reference voltage may be used to disable the functionality of the chip by putting the chip in a resetting mode if the crack detection line is broken or severely damaged.

FIG. 5b shows another embodiment of a test circuit 505. The test circuit 505 may provide an arrangement for testing the crack detection line together with other test functionalities. For example, test circuit 505 may be configured to also test a resistance of an airbag coil. In the embodiment of the test circuit 505 the first terminal 112a of the crack detection line 112a is electrically connected via MUX 534 to a first input of the amplifier AMP 550 and the second terminal 112a of the crack detection line 130 is electrically connected to the second input of the amplifier AMP 540 via MUX 532. The amplifier AMP 550 may be buffered from the output AO 570 via output buffer 560.

FIG. 6 shows a flow chart 600 for setting a reference value in a crack reliability test program and testing a plurality of chips with the crack reliability test program. In one embodiment a threshold voltage is determined, wherein the threshold voltage is a voltage below which the chip passes the crack reliability test and above which the chip fails the crack reliability test.

In a first step 610, the resistances of the crack detection lines are tested and voltages are measured for a plurality of n chips, for example. In a second step 620, the tested chips are evaluated and a threshold or reference voltage is determined based on the evaluated chips. For example, the evaluation of the chips may result in a setting of a threshold voltage. The threshold voltage is a voltage below which the chip is considered reliable and above which the chip is not considered reliable. The threshold voltage may include a safety margin. Alternatively, the reference voltage may be found statistically. In a third step 630 the threshold voltage is set as a reference voltage in a crack reliability test program. In a final step 640 each chip is tested with the crack reliability test program and based on this test it is decided whether or not the chip is reliable.

The chips pass the reliability test if the measured voltage is below the reference voltage and fail if the measured voltage is above the reference voltage. Of course, the test circuit can be rearranged so that a chip passes when the tested voltage is above the reference voltage and fails when the tested voltage is below the reference voltage.

Although the present invention and its advantages have been described in detail, it should be understood that various changes, substitutions and alterations can be made herein without departing from the spirit and scope of the invention as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor device comprising:
a crack detection line within a chip, the crack detection line surrounding an inner area of the chip, wherein the crack detection line comprises a first terminal and a second terminal;
a test circuit connected to the first terminal and the second terminal, the test circuit configured to measure a signal over the crack detection line; and
an output terminal, the output terminal connected to the test circuit and configured to provide a measured signal.

2. The semiconductor device according to claim 1, wherein the crack detection line is arranged next to a crack stop barrier surrounding the inner area of the chip.

3. The semiconductor device according to claim 1, wherein the inner area comprises an integrated circuit.

4. The semiconductor device according to claim 1, wherein the crack detection line comprises at least one conductive segment in an interconnect structure and at least one substrate conductive segment in a substrate.

5. The semiconductor device according to claim 4, wherein the crack detection line comprises a first conductive segment in a first metallization layer, a second conductive segment in a second metallization layer and a substrate conductive segment in the substrate.

6. The semiconductor device according to claim 4, wherein the substrate conductive segment comprises highly doped lines in the substrate.

7. A method of manufacturing a semiconductor device, the method comprising:
forming a crack detection line surrounding an integrated circuit;
forming test circuit in the integrated circuit, the test circuit connected to the crack detection line; and
forming an output terminal, the output terminal connected to the test circuit.

8. The method according to claim 7, wherein forming the crack detection line comprises forming a substrate conductive segment in a substrate and forming a first conductive segment in a first metallization layer.

9. The method according to claim 8, further comprising forming a second conductive segment in a second metallization layer.

10. The method according to claim 8, wherein the substrate conductive segment comprises a plurality of substrate conductive segments, wherein the first conductive segment comprises a plurality of conductive segments, and wherein the plurality of substrate conductive segments and the plurality of conductive segments are electrically connected through plugs/vias and/or contacts.

11. The method according to claim 8, wherein forming the substrate conductive segment comprises forming a highly doped line in the substrate.

12. A method for testing a semiconductor device, the method comprising:
providing a semiconductor chip having a crack detection line;
measuring an analog signal over the crack detection line; and
reading the analog signal from an output terminal.

13. The method according to claim 12, wherein measuring the analog signal comprises measuring a resistance.

14. The method according to claim 12, further comprising determining whether a value of the analog signal is above or below a predetermined reference value.

15. The method according to claim 12, wherein the crack detection line is partially located in a semiconductor substrate of the semiconductor chip.

16. A method for setting a reference value for an analog signal of a semiconductor device, the method comprising:
testing n semiconductor devices according to claim 12, the testing providing n test results;
evaluating the n test results; and
statistically determining the reference value for the analog signal of the semiconductor device.

17. A semiconductor device comprising:
a crack detection line within a chip, wherein the crack detection line is arranged next to a crack stop barrier surrounding an inner area of the chip, and wherein the crack detection line comprises at least one conductive segment in an interconnect structure and at least one substrate conductive segment in a substrate.

18. The semiconductor device according to claim 17, wherein the crack detection line comprises a first conductive segment in a first metallization layer of the interconnect structure, a second conductive segment in a second metallization layer of the interconnect structure and a substrate conductive segment in the substrate.

19. The semiconductor device according to claim 17, wherein the substrate conductive segment comprises a highly doped line in the substrate.

20. The semiconductor device according to claim 17, wherein the crack detection line is arranged between the crack stop barrier and the inner area.
